(19) United States
(12) Patent Application Publication
(10) Pub. No.: US 2018/0006088 A1
(43) Pub. Date: Jan. 4, 2018

(54) RESISTIVE RANDOM ACCESS MEMORY (ReRAM) DEVICE

(71) Applicant: Hewlett Packard Enterprise Development LP, Houston, TX (US)

(72) Inventors: Xia Sheng, Palo Alto, CA (US); Kyung Min, Palo Alto, CA (US); Gary Gibson, Palo Alto, CA (US)

(21) Appl. No.: 15/539,929

(22) PCT Filed: Jan. 26, 2015
(86) PCT No.: PCT/US2015/012898

§ 371 Date: Jun. 26, 2017

(51) Int. Cl. H01L 27/24; H01L 45/00

(52) U.S. Cl. CPC H01L 27/2463; H01L 45/1253

(57) ABSTRACT

One example includes a resistive random access memory (ReRAM) device. The device includes a set of electrodes to receive a voltage. The device also includes a memristor element to at least one of store and readout a memory state in response to a current that flows through the ReRAM device in response to the voltage. The device further includes a selector element having a dynamic current-density area with respect to the voltage.

### BACKGROUND

Memory arrays are implemented in a variety of computer applications. An example of a memory array is a random access memory (RAM) that can be arranged as an array of memory cells in rows and columns. Some RAM systems implement transistors as memory elements to store a digital bit having one of two logic states in each memory cell. As another example, a RAM system can be configured as a resistive random access memory (ReRAM) memory system. A ReRAM memory system operates by changing a resistance across a dielectric solid-state material, which can be a memristive device.

### BRIEF DESCRIPTION OF THE DRAWINGS

FIG. 1 illustrates an example diagram of a resistive random access memory (ReRAM) device.

FIG. 2 illustrates an example of a ReRAM device.

FIG. 3 illustrates an example diagram of current-density area in a ReRAM device.

FIG. 4 illustrates another example of a ReRAM device.

FIG. 5 illustrates yet another example of a ReRAM device.

FIG. 6 illustrates a ReRAM memory system.

### DETAILED DESCRIPTION

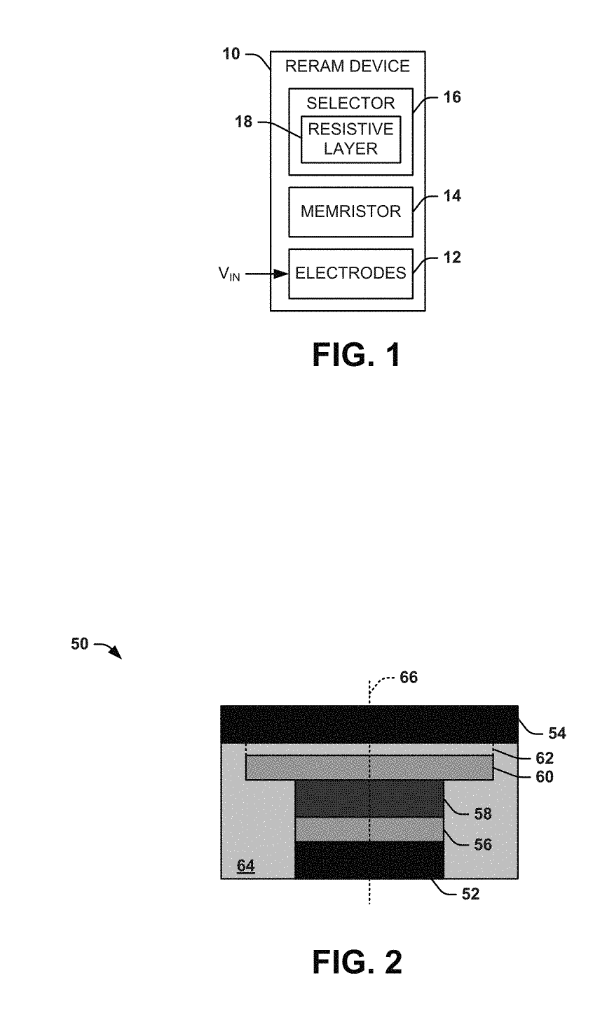

FIG. 1 illustrates an example diagram of a resistive random access memory (ReRAM) device 10. The ReRAM device 10 can correspond to a single memory cell in a ReRAM memory system, such as including a plurality of ReRAM devices 10 that are arranged in an array of rows and columns. The ReRAM device 10 includes a set of electrodes 12 that are configured to receive a voltage V_{IN} that can be applied during at least one of a read and a write operation. The ReRAM device 10 also includes a memristor element 14 and a selector element 16. The memristor element 14 is configured to store a digital bit having one of two logic states in the ReRAM device 10, and the selector element 16 is configured to allow selection of the ReRAM device 10 for read and/or write operations, and can be configured to suppress current flow through the ReRAM device 10 when the ReRAM device 10 is unselected for read/write operations via the voltage V_{IN}.

For example, the selector element 16 is in an “ON” state (e.g., a low resistance state) when the ReRAM device 10 is selected in response to a sufficient amplitude of the voltage V_{IN}, and is in an “OFF” state (i.e., a high resistance state) when the ReRAM device 10 is not selected based on a lower amplitude of the voltage V_{IN} (e.g., less than sufficient for activation). The selector element 16 can thus exhibit a high resistance in the “OFF” state to substantially mitigate a “sneak path” current flow through the ReRAM device 10 in the “OFF” state. As described herein, the selector element 16 is responsive to a current that is provided through the ReRAM device 10 in response to the voltage V_{IN} to provide a dynamic current-density area with respect to the current to allow the ReRAM device 10 to also operate with both a high resistance at a low amplitude of the voltage V_{IN}, and a low resistance at higher amplitudes of the voltage V_{IN}, and therefore with high non-linearity, as opposed to typical memristive devices. The low resistance of the selector element 16 in the “ON” state ensures that the voltage V_{IN} is largely applied across the memristor element 14 of the selected ReRAM device 10.

In the example of FIG. 1, the selector element 16 includes a resistive layer 18. The resistive layer 18 can have a non-linear resistivity (e.g., a resistivity that decreases with increasing applied electric field). Moreover, the resistivity of the resistive layer 18 can be anisotropic. As an example, the resistivity of the resistive layer 18 can be larger in the cross-sectional plane of the resistive layer 18 than perpendicular to the plane of the resistive layer 18 over some range of the applied bias V_{IN}, corresponding to a range of local electric fields within the resistive layer 18. Furthermore, the non-linearity of the in-plane and out-of-plane resistivities of the resistive layer 18 can be different, such that the ratio of in-plane to out-of-plane resistivities can change with the voltage V_{IN}. As an example, the ratio of in-plane to out-of-plane resistivity can decrease with increasing amplitudes of the voltage V_{IN}.

The resistive layer 18 can be separated from one of the electrodes 12 by an insulator to form a barrier layer or interface (e.g., a tunneling barrier layer or a Schottky barrier interface) that can help to provide a low leakage current in an “OFF” state of the ReRAM device 10 and can provide high non-linearity of the current through the ReRAM device 10 in response to the voltage V_{IN}. The combination of the resistive layer 18 and the associated barrier layer or interface can provide an effective anisotropy in in-plane and out-of-plane device resistivity. In some embodiments, this combination may also provide different non-linearities with respect to applied bias of the voltage V_{IN} for in-plane versus out-of-plane electrical conduction. As an example, the resistive layer 18 along with the associated barrier layer or interface can be configured to limit the current through the ReRAM device 10, such that the resistive layer 18 and associated barrier layer or interface provides a high resistance at low amplitudes of the voltage V_{IN}, and provides a low resistance at high amplitudes of the voltage V_{IN} as the device is selected.

In addition, the resistive layer 18 can be fabricated in the ReRAM device 10 such that the resistive layer 18 (e.g., and an associated barrier layer or interface) can have a dynamic current-density area with respect to the voltage applied to ReRAM device 10. As described herein, the term “dynamic current-density area” describes that the area through which the bulk of the current flows can vary depending on the applied bias of the voltage V_{IN} due to a variable difference in resistivity of portions of the resistive layer 18 (e.g., and an associated barrier layer or interface) with respect to a current path of the current through the resistive layer 18 through which the current flows, such that the distribution of the current flow through the respective portions of the resistive layer 18 is variable. The portions can correspond to a first portion directly overlying the memristor element 14 relative to portions that are peripheral to or not overlying the memristor element 14, such that the dynamic current-density area results from a variable ratio of the resistivity of the portions of the cross-sectional area of the ReRAM device 10. Therefore, at smaller amplitudes of the current flowing through the ReRAM device 10 in response to a low amplitude of the voltage V_{IN}, the current-density area of the resistive layer 18 (e.g., and the associated barrier layer or interface) can be smaller due to a greater difference of resistivity between the respective portions of the resistive layer 18. Conversely, at greater amplitudes of the current flowing through the ReRAM device 10 in response to a high amplitude of the voltage V_{IN}, the current-density area of the resistive layer 18 (e.g., and the associated barrier layer or interface) can be larger due to a smaller difference of resistivity between the respective portions of the resistive layer 18.

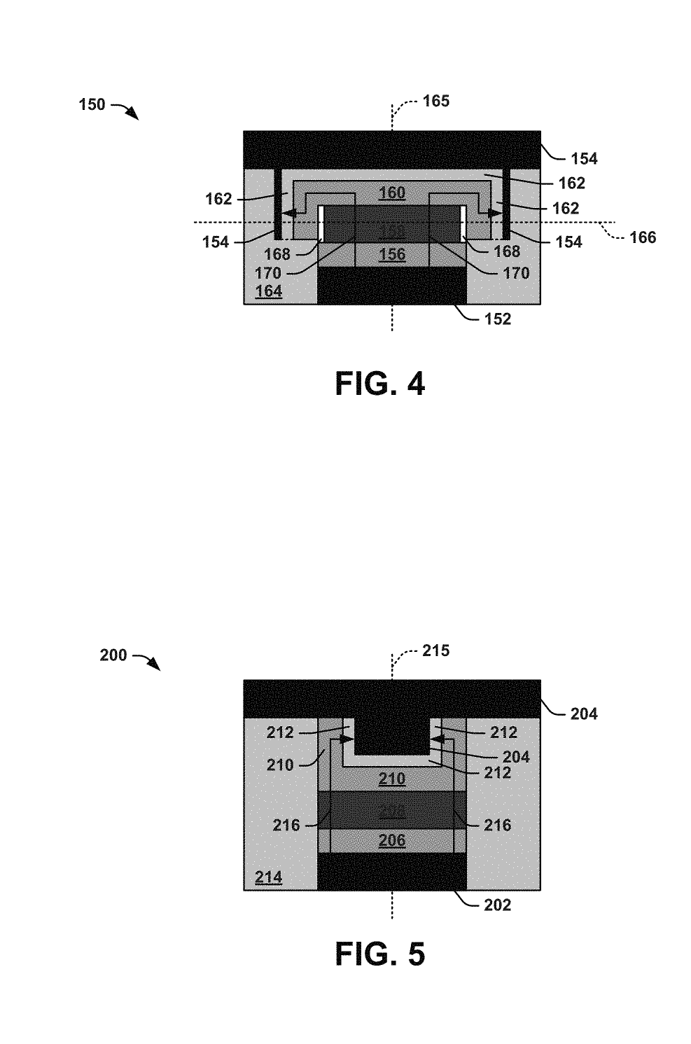

As an example, the selector element 16 (e.g., including both the resistive layer 18 and the associated barrier layer or interface) can each have a cross-sectional area with respect to an axis extending between the set of electrodes 12 that is different from a respective cross-sectional area of the memristor element 14. As described herein, and as particularly demonstrated in the examples of FIGS. 4 and 5, the term “layer” describes an arrangement of material that is not limited to a thickness of a material deposition that is bounded by two planar surfaces, but can include a three-dimensional arrangement of all of the material of the associated “layer”. Therefore, as described herein, portions of a respective material layer can extend beyond other portions of the respective material layer in the axial direction parallel to the axis extending between the electrodes 12.

As an example, the cross-sectional area of the selector element 16 along the axial length between the set of electrodes 12 can be greater than the cross-sectional area of the memristor element 14. As another example, a portion of each of one of the electrodes 12 and the selector element 16 can extend along an axial length between the set of electrodes 12 relative to remaining respective portions of the respective one of the electrodes 12 and the selector element 16. As yet another example, at least one of a surface of the resistive layer 18 and one of the electrodes 12 can be fabricated in a predetermined manner to have a surface roughness to increase a surface area of the respective one of the surface of the resistive layer 18 and the respective one of the electrodes 12. Accordingly, a current-density area of the selector element 16 can be variable relative to the memristor element 14 with respect to the amplitude of the current. For example, a large current-density area in the “ON” state resulting from a sufficiently large amplitude of the voltage V_{IN} contributes to a smaller drop of the portion of the voltage V_{IN} across the resistive layer 18, and therefore ensures that the voltage V_{IN} is mainly applied across the memristor element 14 to perform a read or write operation.

FIG. 2 illustrates an example of a ReRAM device 50. The ReRAM device 50 is one example of the ReRAM device 10 in the example of FIG. 1, and can thus exhibit a low leakage current in an “OFF” state, as well as both a high amplitude of the current in an “ON” state and high non-linearity, as described herein, based on a dynamic current-density area. Similar to as described previously regarding the ReRAM device of the example of FIG. 1, the ReRAM device 50 can correspond to a single memory cell in a ReRAM memory system, such as including a plurality of ReRAM devices 50 that are arranged in an array of rows and columns.

The ReRAM device 50 includes a first electrode 52 and a second electrode 54. The first and second electrodes 52 and 54 are configured to receive a voltage (e.g., the voltage V_{IN}) to provide a current flow through the ReRAM device 50. As an example, the first and second electrodes 52 and 54 can be electrically coupled with, or can be part of/integral with, respective row and column conductors that are arranged in a crossbar array in a ReRAM memory system that can each be likewise associated with a plurality of other ReRAM devices (e.g., configured the same as the ReRAM device 50).

The ReRAM device 50 also includes a switching layer 56 overlying the first electrode 52 and a floating electrode 58 overlying the switching layer 56. As described herein, the “overlying” of the layers of the ReRAM device 50 are with respect to the orientation of the ReRAM device 50 demonstrated in the example of FIG. 2. However, it is to be understood that the orientation of the ReRAM device 50 can be reversed. The switching layer 56 can correspond to a memristive material that is configured to store a digital bit having one of two logic states, such that the digital bit can be written to and read from the switching layer 56 in response to the current flowing through the ReRAM device 50. The floating electrode 58 is configured as a conductor to provide ions or oxygen vacancy to the switching layer 56, as well as to facilitate the current flow through the ReRAM device 50 to an associated selector element (e.g., the selector element 16). In the example of FIG. 2, the switching layer 56 and the floating electrode 58 can collectively correspond to a memristor element (e.g., the memristor element 14). While the ReRAM device 50 in the example of FIG. 2 demonstrates the inclusion of the floating electrode 58, it is to be understood that the floating electrode 58 can be omitted, such that the switching layer 56 could be in direct electrical contact with the selector element.

The ReRAM device 50 also includes a resistive layer 60 overlying the floating electrode 58. The resistive layer 60 can correspond to a variety of different types of materials to provide resistivity with respect to the current that flows through the ReRAM device 50. As an example, the resistive layer 60 can be a thin layer (e.g., 1-10 nm) of a semiconductor material or a conductive material. For example, the resistive layer 60 can be a thin layer of a metal (e.g., amorphous or polycrystalline Pt, Ti, or Ta), a conductive oxide (e.g., TiO_{X}, TaO_{X}, or ZnO), a conductive nitride (e.g., TiN, TaN, NbN, or AlN), or a semiconductor material (e.g., Si or a poly-Si). The material can be deposited by a variety of conventional deposition methods, such as sputtering, evaporation, chemical vapor deposition (CVD), atomic layer deposition (ALD), or a variety of other methods. The resistive layer 60 is separated from the second electrode 54 by a barrier layer 62. As an example, the barrier layer 62 can be a tunneling barrier layer or a layer that forms a Schottky interface with a neighboring layer. For example, the barrier layer 62 can be formed from a variety of oxide, carbide, or nitride insulating materials to provide a greater resistance than the resistive layer 60. As another example, one or both of the resistive layer 60 and the barrier layer 62 can be formed from a material or set of materials that exhibit anisotropic electrical conduction. Additionally, the ReRAM device 50 includes an interlayer dielectric (ILD) material 64 that substantially surrounds the first electrode 52, the switching layer 56, the floating electrode 58, the resistive layer 60, and the barrier layer 62 (e.g., and the second electrode 54). As an example, the barrier layer 62 can be integral with the ILD material 64, such that the ILD material 64 interconnects the resistive layer 60 and the second electrode 54 to form the barrier layer 62. Alternatively, the barrier layer 62 can be formed from a different material than the ILD material 64.

In the example of FIG. 2, the resistive layer 60, and thus also the barrier layer 62, have a cross-sectional area with respect to the axial length of both the resistive layer 60 and the barrier layer 62 between the electrodes 52 and 54 that is greater than the cross-sectional area of the switching layer 56 (e.g., and the floating electrode 58). As described herein, the term “cross-sectional area” refers to a cross-section of the ReRAM device 50 with respect to a length along an axis 66 that extends between the first and second electrodes 52 and 54, and the term “axial length” refers to a length along the axis 66 extending between the first and second electrodes 52 and 54. Accordingly, the current-density area of the current through the ReRAM device 50 can be dynamic with respect to the resistive layer 60, as well as the barrier layer 62, to provide for both a high non-linearity and a very low resistance in an “ON” state.

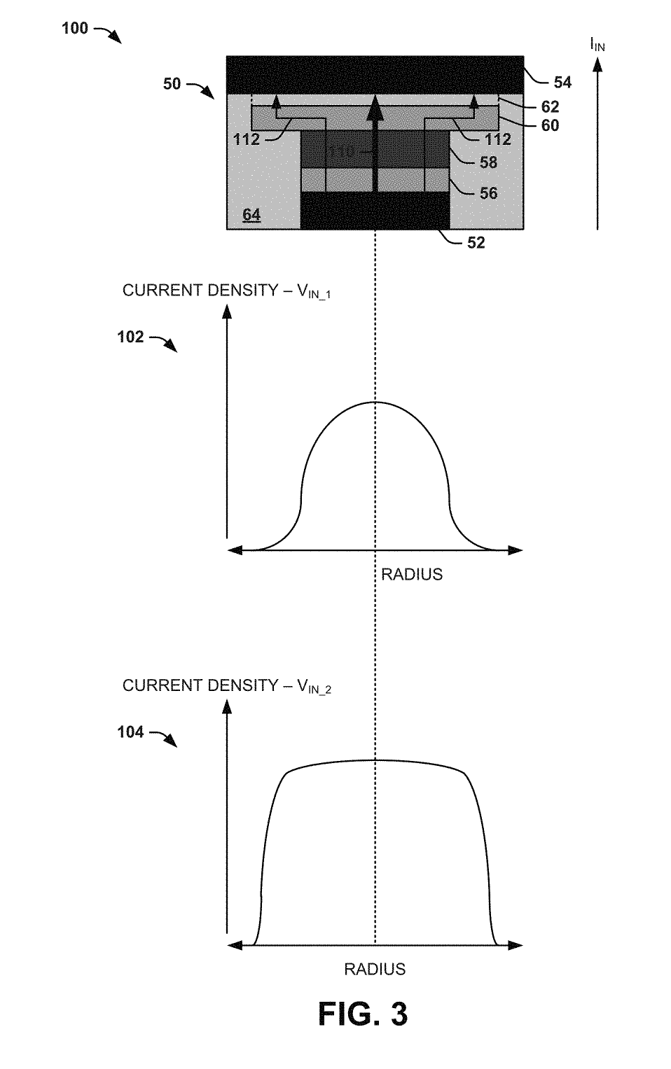

FIG. 3 illustrates an example diagram 100 of current-density area in the ReRAM device 50. The ReRAM device 50 in the example of FIG. 2 is demonstrated again in the example of FIG. 3 to demonstrate current-density area of the resistive layer 60 and the barrier layer 62 in response to the current/voltage. Therefore, like reference numbers are used in the example of FIG. 3 as those demonstrated in the example of FIG. 2.

The diagram 100 demonstrates a voltage V_{IN} applied between the first and second electrodes 52 and 54 to provide a current I_{IN} flowing through the ReRAM device 50. The current I_{IN} is demonstrated as flowing from the first electrode 52 to the second electrode 54 based on a polarity of the voltage V_{IN}. The current I_{IN} can be the integration of current density of the whole cross-sectional area of the ReRAM device 50. As an example, the ReRAM device 50 can be configured as substantially cylindrical, such that the current can be described as follows:

I=∫₀^{R}J(V,r)×2πrdr Equation 1
Where: r is the radius of the resistive layer 60; and
   J(V,r) is the current density at a location r while the voltage V (e.g., the voltage V_{IN}) is applied to ReRAM device 50.
      The direction of the flow of the current I_{IN} thus defines a current path of the current I_{IN} through the ReRAM device 50, as described herein.

The diagram 100 also includes a first graph 102 and a second graph 104 that each plot current density in the plane of the interface between the resistive layer 60 and the barrier layer 62 on a vertical axis relative to a radius (e.g., a distance from an approximate center of the current path of the ReRAM device 50) on a horizontal axis. The graph 102 can correspond to a first amplitude of the voltage V_{IN}, demonstrated as a voltage V_{IN}_{_}₁, and the second graph 104 can correspond to a second amplitude of the voltage V_{IN}, demonstrated as a voltage V_{IN}_{_}₂ that is greater than the first amplitude V_{IN}_{_}₁. The first graph 102 demonstrates a smaller current-density area due to a greater difference between the current density near the center of the interface between the resistive layer 60 and the barrier layer 62 and portions of this interface having an increased distance from the approximate center of the current path. Conversely, the second graph 104 demonstrates a larger current-density area due to a smaller difference between the current density near the approximate center of the conductive path and portions of the conductive path at greater radii from the approximate center of the conductive path. The increase in current density area at higher amplitudes of the voltage V_{IN} occurs because of the corresponding changes in the anisotropy of the electrical conduction through 60 and 62, specifically an increase in the ratio of in-plane to out-of-plane electrical conduction.

Thus, as demonstrated in the example of FIG. 3, the current-density area of the resistive layer 60 and the barrier layer 62, and thus the selector element 16, increases as the amplitude of the current I_{IN} through the ReRAM device 50 increases. In the example of FIG. 3, the current I_{IN} is demonstrated diagrammatically as including a large arrow 110 passing through the ReRAM device 50 from the first electrode 52 to the second electrode 54, as well as two smaller arrows 112 that spread out from the floating electrode 58 in the resistive layer 60 to a greater distance from the large arrow 110. The large arrow 110 thus indicates diagrammatically the current flow of the current I_{IN} through the portion of the switching layer 56 (and the floating electrode 58) at an approximate center of the current path, while the smaller arrows 112 indicate diagrammatically the current flow of the current I_{IN} through the portions of the resistive layer 60 (and the barrier layer 62) that extend along the increased radius to the periphery of the resistive layer 60 (and the barrier layer 62). Accordingly, the diagram 100 demonstrates the dynamic current density-area with respect to the amplitude of the current I_{IN}.

FIG. 4 illustrates another example of a ReRAM device 150. The ReRAM device 150 is another example of the ReRAM device 10 in the example of FIG. 1, and can thus exhibit a low leakage current in an “OFF” state, as well as both a high amplitude of the current in an “ON” state and high non-linearity, as described herein, based on a dynamic current-density area. Similar to as described previously regarding the ReRAM device of the example of FIG. 1, the ReRAM device 150 can correspond to a single memory cell in a ReRAM memory system, such as including a plurality of ReRAM devices 150 that are arranged in an array of rows and columns.

The ReRAM device 150 includes a first electrode 152 and a second electrode 154. The first and second electrodes 152 and 154 are configured to receive a voltage (e.g., the voltage V_{IN}) to provide a current flow through the ReRAM device 150. As an example, the first and second electrodes 152 and 154 can be electrically coupled with, or can be part of/integral with, respective row and column conductors that are arranged in a crossbar array in a ReRAM memory system that can each be likewise associated with a plurality of other ReRAM devices (e.g., configured the same as the ReRAM device 150).

The ReRAM device 150 also includes a switching layer 156 overlying the first electrode 152 and a floating electrode 158 overlying the switching layer 156. The switching layer 156 can correspond to a memristive material that is configured to store a digital bit having one of two logic states, such that the digital bit can be written to and read from the switching layer 156 in response to the current flowing through the ReRAM device 150. The floating electrode 158 is configured as a conductor to facilitate the current flow through the ReRAM device 150 to an associated selector element (e.g., the selector element 16). In the example of FIG. 4, the switching layer 156 and the floating electrode 158 can collectively correspond to a memristor element (e.g., the memristor element 14).

The ReRAM device 150 also includes a resistive layer 160 overlying the floating electrode 158. The resistive layer 160 is separated from the second electrode 154 by a barrier layer 162. Additionally, the ReRAM device 150 includes an interlayer dielectric (ILD) material 164 that substantially surrounds the first electrode 152, the switching layer 156, the floating electrode 158, the resistive layer 160, and the barrier layer 162 (e.g., and the second electrode 154). As an example, the barrier layer 162 can be integral with the ILD material 164, such that the ILD material 164 interconnects the resistive layer 160 and the second electrode 154 to form the barrier layer 162. Alternatively, the barrier layer 162 can be formed from a different material than the ILD material 164.

A portion of each of one of the second electrode 154, the resistive layer 160, and the barrier layer 162 are arranged to extend axially along an axis 165 relative to remaining respective portions of the second electrode 154, the resistive layer 160, and the barrier layer 162. In the example of FIG. 4, a cross-section of the ReRAM device 150 with respect to the axis 165 is demonstrated by the dotted line 166. The cross-section 166 extends through a portion of the floating electrode 158, and also extends through the portion of the resistive layer 160, the portion of the barrier layer 162, and the portion of the second electrode 154. In the example of FIG. 4, the ReRAM device 150 further comprises an insulator 168 interconnecting the portion of the resistive layer 160 and the floating electrode 158. Therefore, the current I_{IN} can flow laterally and down (e.g., having a vector component anti-parallel with respect to the axial length between the electrodes 152 and 154) from the portion of the resistive layer 160 through the portion of the barrier layer 162 to the portion of the second electrode 154, as demonstrated by the smaller arrows 170, in response to increasing amplitudes of the current I_{IN}. The insulator 168 can be formed, for example, by growing the insulating material surrounding the floating electrode 158 using a conformal growth method such as CVD or ALD, and removing the material of the insulator 168 on top of the floating electrode 158 via a planarization process, such as chemical mechanical polishing (CMP). Accordingly, based on the arrangement of the portions of the resistive layer 160, the barrier layer 162, and the second electrode 154, the current-density area of the current through the ReRAM device 150 can be dynamic with respect to the resistive layer 160, as well as the barrier layer 162, to provide for both a high amplitude of the current in an “ON” state and high non-linearity, similar to as described previously in the example of FIGS. 2 and 3. It is to be understood that the ReRAM device 150 is not limited to the arrangement demonstrated in the example of FIG. 4. For example, the floating electrode 158 could be omitted, such that the resistive layer 160 could overly the switching layer 156, and the insulator 168 can instead substantially surround the switching layer 156 to interconnect the switching layer 156 and the resistive layer 160.

FIG. 5 illustrates yet another example of a ReRAM device 200. The ReRAM device 200 is another example of the ReRAM device 10 in the example of FIG. 1, and can thus exhibit a low leakage current in an “OFF” state, as well as both a high amplitude of the current in an “ON” state and high non-linearity, as described herein, based on a dynamic current-density area. Similar to as described previously regarding the ReRAM device of the example of FIG. 1, the ReRAM device 200 can correspond to a single memory cell in a ReRAM memory system, such as including a plurality of ReRAM devices 200 that are arranged in an array of rows and columns.

The ReRAM device 200 includes a first electrode 202 and a second electrode 204. The first and second electrodes 202 and 204 are configured to receive a voltage (e.g., the voltage V_{IN}) to provide a current flow through the ReRAM device 200. As an example, the first and second electrodes 202 and 204 can be electrically coupled with, or can be part of/integral with, respective row and column conductors that are arranged in a crossbar array in a ReRAM memory system that can each be likewise associated with a plurality of other ReRAM devices (e.g., configured the same as the ReRAM device 200).

The ReRAM device 200 also includes a switching layer 206 overlying the first electrode 202 and a floating electrode 208 overlying the switching layer 206. The switching layer 206 can correspond to a memristive material that is configured to store a digital bit having one of two logic states, such that the digital bit can be written to and read from the switching layer 206 in response to the current flowing through the ReRAM device 200. The floating electrode 208 is configured as a conductor to facilitate the current flow through the ReRAM device 200 to an associated selector element (e.g., the selector element 16). In the example of FIG. 5, the switching layer 206 and the floating electrode 208 can collectively correspond to a memristor element (e.g., the memristor element 14).

The ReRAM device 200 also includes a resistive layer 210 overlying the floating electrode 208. The resistive layer 210 is separated from the second electrode 204 by a barrier layer 212. Additionally, the ReRAM device 200 includes an interlayer dielectric (ILD) material 214 that substantially surrounds the first electrode 202, the switching layer 206, the floating electrode 208, the resistive layer 210, and the barrier layer 212 (e.g., and the second electrode 204). As an example, the barrier layer 212 can be integral with the ILD material 214, such that the ILD material 214 interconnects the resistive layer 210 and the second electrode 204 to form the barrier layer 212. Alternatively, the barrier layer 212 can be formed from a different material than the ILD material 214.

Similar to as described previously in the example of FIG. 4, a portion of each of one of the second electrode 204, the resistive layer 210, and the barrier layer 212 are arranged to extend axially parallel along an axis 215 between the electrodes 202 and 204 relative to remaining respective portions of the second electrode 204, the resistive layer 210, and the barrier layer 212. In the example of FIG. 5, a portion of the second electrode 204 extends anti-parallel with respect to the axis 215 relative to the remaining portions of the second electrode 204. Additionally, a portion of the resistive layer 210 extends parallel with respect to the axis 215 relative to the remaining portions of the resistive layer 210, with the barrier layer 212 interconnecting the portion of the resistive layer 210 and the portion of the second electrode 204. Therefore, the portion of the resistive layer 210, and thus the portion of the barrier layer 212, at least partially surround the portion of the second electrode 204. As described herein, the term “at least partially surround” refers to one or more contiguous portions of the resistive layer 210 and barrier layer 212, respectively, being arranged laterally with respect to the portion of second electrode 204. Therefore, the portions of resistive layer 210 and barrier layer 212 can be arranged in any variation between a small portion of the resistive layer 210 and barrier layer 212 being arranged next to the portion of the second electrode 204 to completely surrounding the second electrode 204

Therefore, the current I_{IN} can flow up (e.g., having a vector component parallel with respect to the axis 215) and laterally from the portion of the resistive layer 210 through the portion of the barrier layer 212 to the portion of the second electrode 204, as demonstrated by the smaller arrows 216, in response to increasing amplitudes of the current I_{IN}. Accordingly, based on the arrangement of the portions of the resistive layer 210, the barrier layer 212, and the second electrode 204, the current-density area of the current through the ReRAM device 200 can be dynamic with respect to the resistive layer 210, as well as the barrier layer 212, to provide for both a low resistance in an “ON” state and high non-linearity, similar to as described previously in the example of FIGS. 2-4.

It is to be understood that the ReRAM devices 50, 150, and 200 are not limited to the respective examples of FIGS. 2, 4, and 5. For example, a variety of additional combinations of arrangements of the resistive layers 60, 160, and 210, the barrier layers 62, 162, and 212, and the second electrode 54, 154, and 204 can be implemented to provide the dynamic current-density area with respect to the amplitude of the current I_{IN}. As yet another example, the ReRAM devices 50, 150, and 200 are described herein as voltage-driven devices, but could instead be configured as current-driven devices. Therefore, the ReRAM devices 50, 150, and 200 are demonstrated as examples, such that the ReRAM device 10 in the example of FIG. 1 can be configured in a variety of different ways.

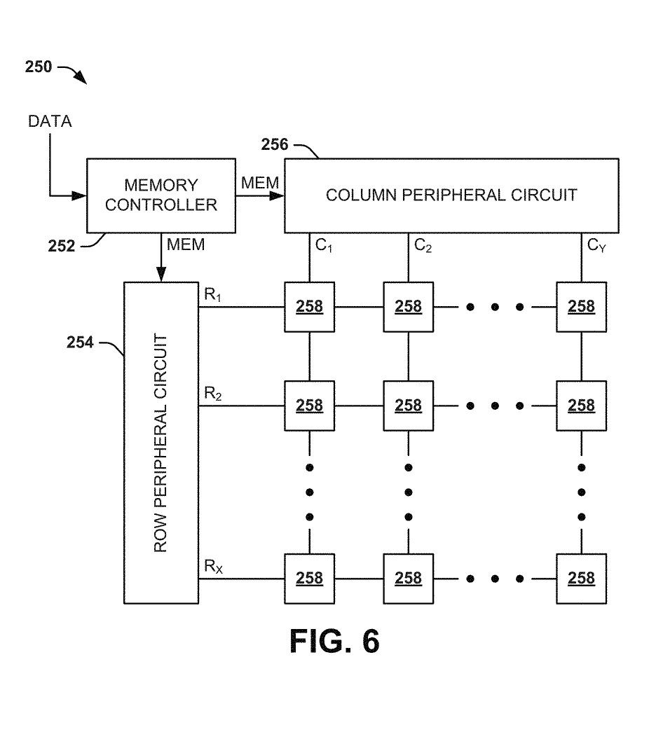

FIG. 6 illustrates a ReRAM memory system 250. The ReRAM memory system 250 can be incorporated as a memory system in a variety of enterprise and consumer electronic products, such as data center storage, servers, desktop, laptop, and tablet computers, portable electronic devices, or a variety of other electronic devices.

The ReRAM memory system 250 includes a memory controller 252. In the example of FIG. 6, the memory controller 252 receives a signal DATA, such as provided from a processor (not shown), that can correspond to memory commands for read/write operations to the ReRAM memory system 250. The memory controller 252 is thus configured to generate peripheral commands MEM associated with the read/write operations. Alternatively, the memory controller 252 can be configured as a processor that generates the signal DATA. In the example of FIG. 6, the memory controller 252 provides the peripheral commands MEM to a row peripheral circuit 254 and a column peripheral circuit 256.

The row peripheral circuit 254 is configured to control a plurality X of memory rows, where X is a positive integer, that each corresponds to a row of an array of ReRAM devices 258 associated with the ReRAM memory system 250. In the example of FIG. 6, the rows are demonstrated as R₁ through R_{X}. Similarly, the column peripheral circuit 256 is configured to control a plurality Y of memory columns, where Y is a positive integer, that each corresponds to a column of the array of ReRAM devices 258 associated with the ReRAM memory system 250. In the example of FIG. 6, the columns are demonstrated as C₁ through C_{Y}. Therefore, the row and column peripheral circuits 254 and 256 are configured to activate and deactivate the ReRAM devices 258 on the ReRAM memory system 250 via voltage signals on both a respective row and column R and C to select a respective one of the ReRAM devices 258 for read and write operations. Other ReRAM devices 258 in a given one of the rows or columns on which a voltage signal is provided can remain unselected based on having an insufficient voltage amplitude for activation (e.g., the selector 16 switching to the “ON” state). Such ReRAM devices 10 can still experience a “sneak path” current, which can be substantially mitigated by a respective resistive layer (e.g., the resistive layer 18).

Each of the ReRAM devices 258 can be configured substantially similar to the ReRAM devices 50, 150, and 200 in the respective examples of FIGS. 2, 4, and 5. Therefore, each of the ReRAM devices 258 includes a set of electrodes that are electrically coupled to orthogonal row and column conductors that are arranged in a crossbar array, such that the set of electrodes of a given one of the ReRAM devices 258 is likewise conductively coupled with each of the ReRAM devices 258 in a respective one of the rows and a respective one of the columns. As an example, the orthogonal row and column conductor arrangement can be the electrodes in each of the ReRAM devices 258, the electrodes can be integral with the row and column conductors, or the electrodes can be electrically coupled with the row and column conductors. Therefore, each of the ReRAM devices 258 can be arranged at an intersection of a respective one of the row conductors and a respective one of the column conductors of the crossbar array. The ReRAM devices 258 also each include a memristor element configured to store a digital bit and a selector element configured to allow selection of the respective one of the ReRAM devices 258 for the read and/or write operations via the row and column peripheral circuits 254 and 256 (via a voltage provided on the respective rows and columns). Additionally, as described previously with respect to the ReRAM devices 50, 150, and 200 in the respective examples of FIGS. 2, 4, and 5, the selector element of each of the ReRAM devices 258 can exhibit a dynamic current-density area with respect to the voltage of the respective ReRAM device 258 to allow current to pass through the respective selected ReRAM device 258, and a low sneak path current in the unselected ReRAM devices 258, as described herein.

What have been described above are examples. It is, of course, not possible to describe every conceivable combination of components or methods, but one of ordinary skill in the art will recognize that many further combinations and permutations are possible. Accordingly, the invention is intended to embrace all such alterations, modifications, and variations that fall within the scope of this application, including the appended claims. Additionally, where the disclosure or claims recite “a,” “an,” “a first,” or “another” element, or the equivalent thereof, it should be interpreted to include one or more than one such element, neither requiring nor excluding two or more such elements. As used herein, the term “includes” means includes but not limited to, and the term “including” means including but not limited to. The term “based on” means based at least in part on.

What is claimed is:

1. A resistive random access memory (ReRAM) device comprising:
a set of electrodes to receive a voltage;
a memristor element to at least one of store and readout a memory state in response to a current that flows through the ReRAM device in response to the voltage; and
a selector element having a dynamic current-density area with respect to the voltage.

2. The device of claim 1, wherein the memristor element comprises a switching layer, wherein the selector element comprises a resistive layer and a barrier layer, each of the barrier layer and the resistive layer having the dynamic current-density area.

3. The device of claim 2, wherein the resistive layer and the barrier layer have a cross-sectional area with respect to an axis extending between the set of electrodes that is greater than at least one of a cross-sectional area of the switching layer and a floating electrode that interconnects the switching layer and the resistive layer.

4. The device of claim 2, wherein the set of electrodes comprises a first electrode that is separated from the resistive layer by the barrier layer, wherein a portion of each of the first electrode, the resistive layer, and the barrier layer extend along an axial length parallel to the axis extending between the set of electrodes relative to remaining respective portions of each of the first electrode, the resistive layer, and the barrier layer, such that the portion of the barrier layer interconnects the portion of the first electrode and the portion of the resistive layer.

5. The device of claim 4, wherein a cross-section of the ReRAM device with respect to an axis extending between the set of electrodes extends through at least a portion of one of the switching layer and a floating electrode that interconnects the switching layer and the resistive layer and through the portion of the resistive layer and the portion of the first electrode, wherein the ReRAM device further comprises an insulator interconnecting the portion of the resistive layer and the one of the switching layer and the floating electrode.

6. The system of claim 4, wherein the portion of the resistive layer and the portion of the barrier layer at least partially surround the portion of the first electrode.

7. The system of claim 2, wherein the set of electrodes comprises a first electrode that is separated from the resistive layer by the barrier layer, wherein at least one of a surface of the resistive layer and the first electrode is fabricated in a predetermined manner to have a surface roughness to increase a surface area of the respective at least one of the surface of the resistive layer and the first electrode.

8. The system of claim 2, wherein at least one of the resistive layer and the barrier layer provides electrical anisotropy.

9. A ReRAM memory system comprising a plurality of ReRAM devices of claim 1 arranged in a crossbar array of a plurality of rows and columns, wherein the set of electrodes in each of the plurality of ReRAM devices comprises:
a first conductor that is associated with each of the plurality of ReRAM devices in a respective one of the plurality of rows; and
a second conductor that is orthogonal with respect to the first conductor and is associated with each of the plurality of ReRAM devices in a respective one of the plurality of columns.

10. A resistive random access memory (ReRAM) device comprising:
a first electrode;
a switching layer overlying the first electrode and being to at least one of store and readout a memory state in response to a current that flows through the ReRAM device;
a resistive layer electrically coupled with the switching layer;
a barrier layer overlying the resistive layer, the barrier layer and the resistive layer each having a cross-sectional area with respect to an axis extending from the first electrode along at least a portion of an axial length of the barrier layer and the resistive layer parallel with the current path that is different from a respective cross-sectional area of the switching layer; and
a second electrode overlying the barrier layer and through which the axis extends from the first electrode, the first and second electrodes being to receive a voltage to provide the current through the ReRAM device.

11. The device of claim 10, wherein the cross-sectional area of the barrier layer and the resistive layer with respect to the axis is fabricated to facilitate a dynamic current-density area with respect to the voltage applied to the first and second electrodes of the ReRAM device.

12. The device of claim 10, wherein the resistive layer and the barrier layer have a cross-sectional area with respect to the axis along the axial length of both the barrier layer and the resistive layer that is greater than the cross-sectional area of at least one of the switching layer and a floating electrode that interconnects the switching layer and the resistive layer.

13. The device of claim 10, wherein the set of electrodes comprises a first electrode that is separated from the resistive layer by the barrier layer, wherein a portion of each of the first electrode, the resistive layer, and the barrier layer extend along an axial length parallel to the axis relative to remaining respective portions of each of the first electrode, the resistive layer, and the barrier layer, such that the portion of the barrier layer interconnects the portion of the first electrode and the portion of the resistive layer.

14. A ReRAM memory system comprising a plurality of ReRAM devices of claim 10 arranged in a crossbar array of a plurality of rows and columns, wherein the first electrode is a first conductor that is associated with each of the plurality of ReRAM devices in a respective one of the plurality of rows, and wherein the second electrode is a second conductor that is orthogonal with respect to the first conductor and is associated with each of the plurality of ReRAM devices in a respective one of the plurality of columns.

15. A resistive random access memory (ReRAM) system comprising:
a plurality of row conductors that are associated with each of a plurality of rows;
a plurality of column conductors that are arranged orthogonal with respect to the plurality of row conductors and that are associated with each of a plurality of columns, the plurality of row conductors and the plurality of column conductors being arranged in a crossbar array; and
a plurality of ReRAM devices arranged in an array in the rows and columns, each of the ReRAM devices comprising:
a memristor element to at least one of store and readout a memory state in response to a current that flows through the respective ReRAM device in response to a voltage provided between a respective one of the plurality of row conductors and a respective one of the plurality of column conductors; and
a selector element having a dynamic current-density area with respect to an amplitude of the current.
